(19) United States
(12) Patent Application Publication
(10) Pub. No.: US 2022/0114042 A1
(43) Pub. Date: Apr. 14, 2022

(54) INTEGRITY INDEX DETECTING METHOD FOR DEVICE BY MEANS OF MULTIPLE CONTROL OUTPUT SIGNAL

(71) Applicant: ITS CO.,LTD., Ulsan (KR)

(72) Inventor: Young Kyu Lee, Ulsan (KR)

(21) Appl. No.: 17/558,889

(22) Filed: Dec. 22, 2021

Related U.S. Application Data
(63) Continuation of application No. PCT/KR2020/007277, filed on Apr. 6, 2020.

(30) Foreign Application Priority Data
Jun. 25, 2019 (KR) 10-2019-0075800

(51) Int. Cl. G06F 11/07; G11C 7/10

(52) U.S. Cl. CPC G06F 11/0772; G06F 11/0775; G11C 7/1051

(57) ABSTRACT

The present invention relates to an integrity index detecting method for a device by means of multiple control output signals which, after establishing an integrity index reference table based on an integrity reference value set based on information collected from a normal device and a defect reference value set based on information collected from a device before a malfunction occurs, outputs an integrity index value indicating an integrity of the device in real time by applying time information collected from the device in real time to the integrity index reference table to provide the integrity index value to a manager.

### CROSS-REFERENCE TO RELATED APPLICATIONS

The present application is a bypass continuation application of currently pending international application No. PCT/KR2020/007277 having an international filing date of Jun. 4, 2020 and designating the United States, the international application claiming a priority date of Jun. 25, 2019 based upon prior filed K.R patent application No. 10-2019-0075800, the entire contents of the aforesaid international application and the aforesaid K.R. patent application being incorporated herein by reference.

### BACKGROUND

The present invention relates to an integrity index detecting method for a device by means of multiple control output signals, and more particularly, to an integrity index detecting method for a device by means of multiple control output signals which, after establishing an integrity index reference table based on an integrity reference value set based on information collected from a normal device and a defect reference value set based on information collected from a device before a malfunction occurs, outputs an integrity index value indicating an integrity of the device in real time by applying time information collected from the device in real time to the integrity index reference table to provide the integrity index value to a manager, thereby allowing the manager to clearly recognize a real-time integrity of the device by means of the integrity index to establish a plan for inspection or management of the device by himself to very actively and stably perform the overall management of the device to significantly reduce safety accident and losses of money due to the sudden malfunction of the device.

Generally, a stable operation is very important for various devices used for an automation process of equipment.

For example, dozens or hundreds of devices are installed in the equipment of large-scale production plants to continuously produce products while interlocking with each other. If any one of the plurality of devices is broken, a tremendous situation in which the entire operation of the equipment is stopped may occur.

In this case, due to the down-time caused by the malfunction of the device, a huge loss may be caused by not only the repair cost of the device, but also the operating cost which is wasted while the equipment is stopped and the business effect.

According to the recent data of the Ministry of Employment and Labor and the Korea Occupational Safety and Health Agency, the total number of casualties resulting from annual industry safety accidents is estimated to be about 100,000 and when it is converted into the cost, it is estimated that 18 trillion won is lost annually.

In order to avoid an unexpected down-time cost, there is an urgent need for a method of providing information about a real-time state of the device to the manager to induce efficient management of the device by performing the inspection and the repair in advance before the malfunction of the device occurs.

### SUMMARY OF INVENTION

The present invention is proposed to solve various problems described above and an object thereof is to provide an integrity index detecting method for a device by means of multiple control output signals which after establishing an integrity index reference table based on an integrity reference value set based on information collected from a normal device and a defect reference value set based on information collected from a device before a malfunction occurs, outputs an integrity index value indicating an integrity of the device in real time by applying time information collected from the device in real time to the integrity index reference table to provide the integrity index value to a manager, thereby allowing the manager to clearly recognize a real-time integrity of the device by means of the integrity index to establish a plan for inspection or management of the device by himself to very actively and stably perform the overall management of the device to significantly reduce safety accident and losses of money due to the sudden malfunction of the device.

In order to achieve the above-described objects, an integrity index detecting method for a device by means of multiple control output signals according to the present invention includes an integrity information collecting step S10 of measuring and collecting at least one time interval between a control output signal and another control output signal among multiple control output signals output from a controller to perform an operation in a normal state of a device which receives the multiple control output signals output from the controller to operate; a defect information collecting step S20 of measuring and collecting at least one time interval between a control output signal and another control output signal among multiple control output signals output from the controller to allow the device which receives multiple control output signals output from the controller to operate to perform one operation in a state before the malfunction occurs and collecting a time interval between a control output signal different from one or more control output signals collected in the integrity information collecting step S10 and the same control output signal; a setting step S30 of setting an integrity reference value and a defect reference value for the time interval between the control output signals based on the time interval information between the control output signals collected in the integrity and defect information collecting steps S10 and S20; a detecting step S40 of collecting the time interval between a control output signal different from one or more control output signals collected in the integrity information collecting step S10 and the same control output signal among multiple control output signals output from the controller to perform an operation of the device in real time and detecting an integrity index value of the device by comparing the collected time interval value between the control output signals and the integrity and defect reference values set in the setting step S30; and an outputting step S50 is a step of outputting the integrity index value detected in the detecting step S40 to provide the integrity index value to the manager and when in the integrity and defect information collecting steps S10 and S20, a plurality of time intervals between the control output signals is collected, integrity and defect reference values for the plurality of collected time intervals between the control output signals are set in the setting step S30.

Further, the detecting step S40 includes: a partitioning procedure S41 of partitioning a section between the integrity reference value and the defect reference value for the time interval between the control output signals set in the setting step S30 into at least two sections; a setting procedure S42 of setting a section partitioned between the integrity reference value and the defect reference value to a first section, a second section, . . . , and an n-th section sequentially from the integrity reference value and at the same time establishing the integrity index reference table by setting an integrity index value for each section; and a detecting procedure S43 of applying the time interval value between the control output signals measured and collected in the device in real time to the integrity index reference table to detect a section corresponding to the measured time interval value and extract the integrity index value of the detected section.

Further, when in the integrity and defect information collecting steps S10 and S20, a plurality of time intervals between the control output signals is collected to set integrity and defect reference values for the time interval between the respective control output signals in the setting step S30, in the detecting step S40, integrity index reference tables for the integrity and defect reference values are individually established by means of the partitioning procedure S41 and the setting procedure S42.

In the detecting step S43, the time interval values between a plurality of control output signals measured and collected in the device in real time to the integrity index reference table established for each time interval to extract, respectively, an integrity index value for the time interval values between the plurality of control output signals measured in real time.

In the outputting step S50, the integrity index values for the time interval values between the plurality of control output signals measured in real time in the detecting step S40 are independently output to be provided or an average of the extracted integrity index values is calculated to be output and provided as one average integrity index value.

As described above, according to the present invention, after establishing an integrity index reference table based on an integrity reference value set based on information collected from a normal device and a defect reference value set based on information collected from a device before a malfunction occurs, an integrity index detecting method for a device by means of multiple control output signals outputs an integrity index value indicating an integrity of the device in real time by applying time information collected from the device in real time to the integrity index reference table to provide the integrity index value to a manager, thereby allowing the manager to clearly recognize a real-time integrity of the device by means of the integrity index to establish a plan for inspection or management of the device by himself to very actively and stably perform the overall management of the device to significantly reduce safety accident and losses of money due to the sudden malfunction of the device.

### DESCRIPTION OF DRAWINGS

FIG. 1 is a flowchart of an integrity index detecting method for a device by means of multiple control output signals according to an exemplary embodiment of the present invention.

FIG. 2 is a view illustrating an integrity information collecting step according to an exemplary embodiment of the present invention.

FIG. 3 is a view illustrating a defect information collecting step according to an exemplary embodiment of the present invention.

FIG. 4 is a view illustrating a partitioning procedure according to an exemplary embodiment of the present invention.

FIG. 5 is a view illustrating a setting procedure according to an exemplary embodiment of the present invention.

FIG. 6 is a view illustrating a detecting procedure according to an exemplary embodiment of the present invention.

FIG. 7 is a view illustrating an example of providing an average integrity index value according to an exemplary embodiment of the present invention.

The technology to be described below may be modified in various forms and has various exemplary embodiments, and thus specific exemplary embodiments will be illustrated in the drawings and described in detail in detailed description. However, this does not limit the technology to be described below within the specific exemplary embodiments, and it should be understood that the present invention covers all the modifications, equivalents and replacements within the technical spirit and technical scope to be described below.

Terms such as first, second, A, or B may be used to describe various components but the components are not limited by the above terms and are used only to distinguish one component from the other component. For example, without departing from the scope of the technology to be described below, a first component may be referred to as a second component, and similarly, a second component may be referred to as a first component. A term of and/or includes a combination of a plurality of related elements or any one of the plurality of related elements. For example, “A and/or B” may be interpreted as “at least one of A and B”.

Unless the context apparently indicates otherwise, it should be understood that the singular expression includes plural expression. Further, it should be understood that terms “include” and the like indicate that a feature, a number, a step, an operation, a component, a part or the combination thoseof described in the specification is present, but do not exclude a possibility of presence or addition of one or more other features, numbers, steps, operations, components, parts or combinations thereof.

Prior to a detailed description for the drawings, it is intended to clarify that the components in the present specification are merely classified according to a main function of each component. That is, two or more components to be described below may be combined as one component or one component may be divided into two or more components for every subdivided function. Further, each component to be described below may further perform a part or all of the function, which is performed by the other component, as well as a main function to be performed by itself and a partial function or the main function of each component may be exclusively performed by the other component.

When a method or an operating method is performed, processes which constitute the method may be performed in a different order from the mentioned order unless a specific order is clearly mentioned in context. That is, the processes may be performed in the order as described or simultaneously, or an opposite order.

### DETAILED DESCRIPTION

An integrity index detecting method for a device by means of multiple control output signals according to a preferred exemplary embodiment of the present invention will be described in detail based on the accompanying drawings. A detailed description of known functions and configurations determined to unnecessarily obscure the gist of the present invention will be omitted.

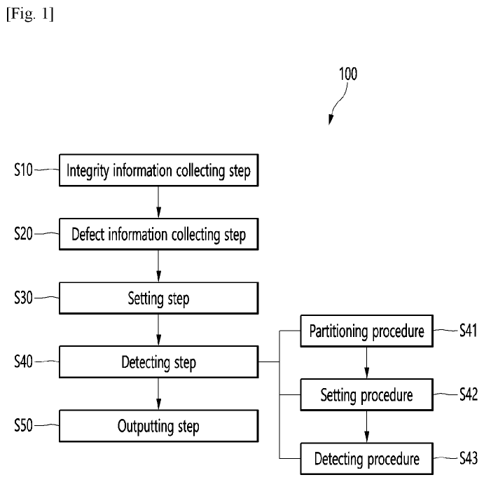

FIG. 1 is a flowchart of an integrity index detecting method for a device by means of multiple control output signals according to an exemplary embodiment of the present invention.

As illustrated in FIG. 1, the integrity index detecting method 100 for a device by means of multiple control output signals according to an exemplary embodiment of the present invention includes an integrity information collecting step S10, a defect information collecting step S20, a setting step S30, a detecting step S40, and an outputting step S50.

The integrity information collecting step S10 is a step of collecting at least one time interval between a control output signal and another control output signal among multiple control output signals output from the controller to perform an operation in a normal state of a device which receives the multiple control output signals output from the controller to operate.

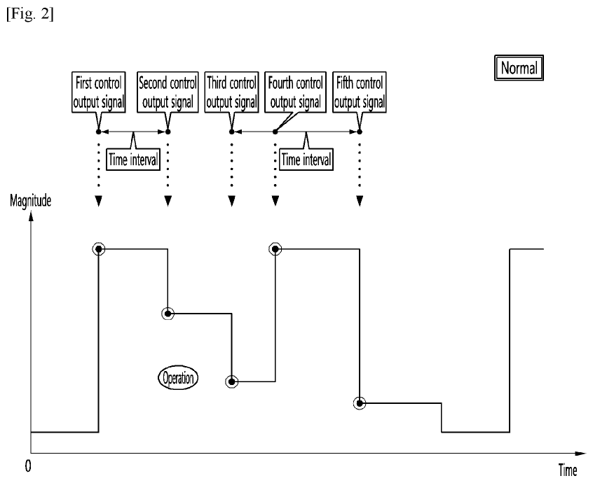

Generally, in order to allow the device to perform an operation, the device receives a control output signal from the controller to perform an operation and for example, a device such as a robot arm which is configured by a plurality of driving units to convey materials receives a plurality of control output signals from the controller to perform one operation of conveying materials and operates while controlling the respective driving units. The operation process of the device is as illustrated in FIG. 2.

FIG. 2 is a view illustrating an integrity information collecting step according to an exemplary embodiment of the present disclosure.

A waveform illustrated in FIG. 2 illustrates an energy (power) value consumed during a process that the device performs an operation over time, for the convenience of description.

Referring to FIG. 2, in the integrity information collecting step S10, a time interval between one or more control output signals among five control output signals transmitted to allow the device to perform one operation in a normal state of the device is collected. For example, five control output signals are defined sequentially as a first control output signal, . . . , and a fifth control output signal and a time interval between the first control output signal and the second control output signal and a time interval between the third control output signal and the fifth control output signal are measured and collected to collect a total of two time interval information between control output signals.

The time interval information between two control output signals collected as described above becomes a basis of an integrity reference value set to detect the integrity of the device in the setting step S30 to be described below.

Here, as an example, it is described that the number of control output signals transmitted to the device to control the operation of the device is determined as five and the time interval information between two control output signals among the control output signals is collected, the number is not limited thereto.

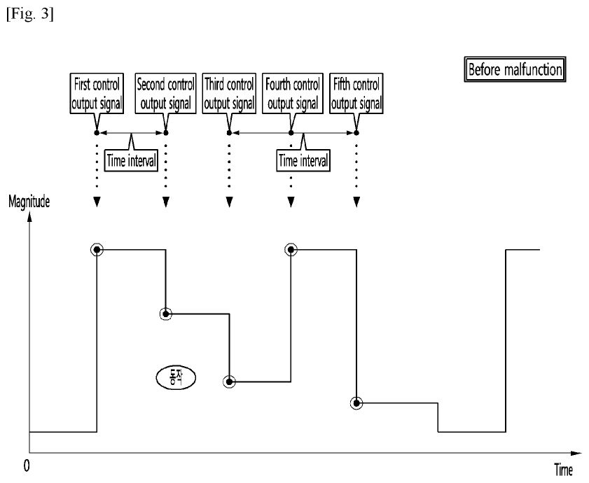

FIG. 3 is a view illustrating a defect information collecting step according to an exemplary embodiment of the present invention.

As illustrated in FIG. 3, the defect information collecting step S20 is a step of measuring and collecting at least one time interval between a control output signal and another control output signal among multiple control output signals output from the controller to allow the device which receives multiple control output signals output from the controller to operate to perform one operation in a state before the malfunction occurs and collecting a time interval between a control output signal different from one or more control output signals collected in the integrity information collecting step S10 and the same control output signal.

That is, in the defect information collecting step S20, like the integrity information collecting step S10, time interval information between two control output signals (first and second control output signals and third and fifth control output signals) is collected and the time interval information between the control output signals collected as described above becomes a basis of a defect reference value set to detect the integrity of the device in the setting step S30.

Here, it is understood that the time interval between the control output signals output from the controller to control the operation of the device illustrated in FIG. 3 is longer than the time interval between the control output signals output from the controller to control an operation of the device illustrated in FIG. 2. By doing this, it is assumed that the worse the state of the device, the longer the time consumed for an operation performed by the device so that the time between the control output signals output from the controller is also naturally increased.

The setting step S30 is a step of setting an integrity reference value and a defect reference value for the time interval between the control output signals based on the time interval information between the control output signals collected in the integrity and defect information collecting steps S10 and S20.

That is, in the integrity and defect information collecting steps S10 and S20, a total of two time interval information between control output signals is set so that an integrity reference value and a defect reference value for the two time intervals between control output signals are set in the setting step S30, respectively. Therefore, in the setting step s30, a total of two integrity and defect reference values are set.

Here, the integrity reference value is set based on the time interval information between the control output signals collected in the integrity information collecting step S10 and the defect reference value is set based on the time interval values which abnormally change (increase) before the malfunction of the device occurs based on the time interval information between the control output signals collected in the defect information collecting step S20.

In the detecting step S40, the time interval between a control output signal different from one or more control output signals collected in the integrity information collecting step S10 and the same control output signal among multiple control output signals output from the controller to perform an operation of the device in real time is collected and an integrity index value of the device is detected by comparing the collected time interval value between the control output signals and the integrity and defect reference values set in the setting step S30. The detecting step is configured by a partitioning procedure S41, a setting procedure S42, and a detecting procedure S43.

The partitioning procedure S41 is a procedure of partitioning a section between the integrity reference value and the defect reference value for the time interval between the control output signals set in the setting step S30 into at least two sections.

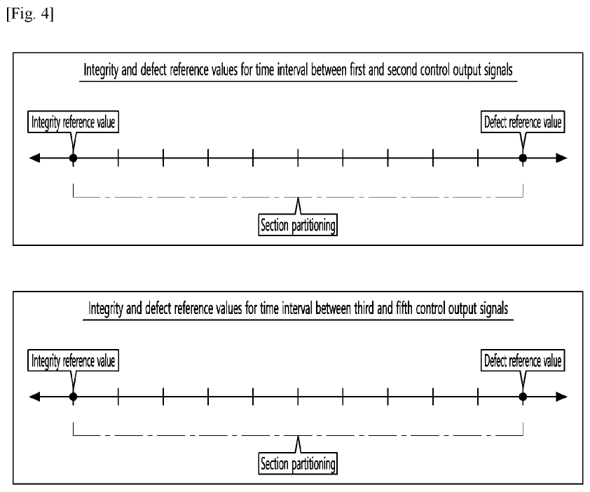

That is, there is a (magnitude) difference between the integrity reference value and the defect reference value and a section between the integrity reference value and the defect reference value is formed by the difference. This section is partitioned into two or more sections with the same interval. In the setting step S30, the integrity and defect reference values for the time interval value between the first and second control output signals and the integrity and defect reference values for the time interval value between the third and fifth control output signals are set so that as illustrated in FIG. 4, in the partitioning procedure S41, the integrity and defect reference values are partitioned.

FIG. 4 is a view illustrating a partitioning procedure according to an exemplary embodiment of the present invention.

In the present exemplary embodiment, when the section between the integrity reference value and the defect reference value is partitioned, the number of times of partitioning of the section is set depending on how precisely detect the integrity of the device in the detecting procedure S43 to be described below. For example, as compared with the partitioning between the integrity reference value and the defect reference value into 10 sections, when the section between the integrity reference value and the defect reference value is partitioned into 100 sections, the integrity of the device may be more precisely detected.

In the integrity index detecting method 100 for a device by means of multiple control output signals of the present invention, the section between the integrity reference value and the defect reference value is partitioned into 10 sections, but the number of partitioned sections is not limited thereto.

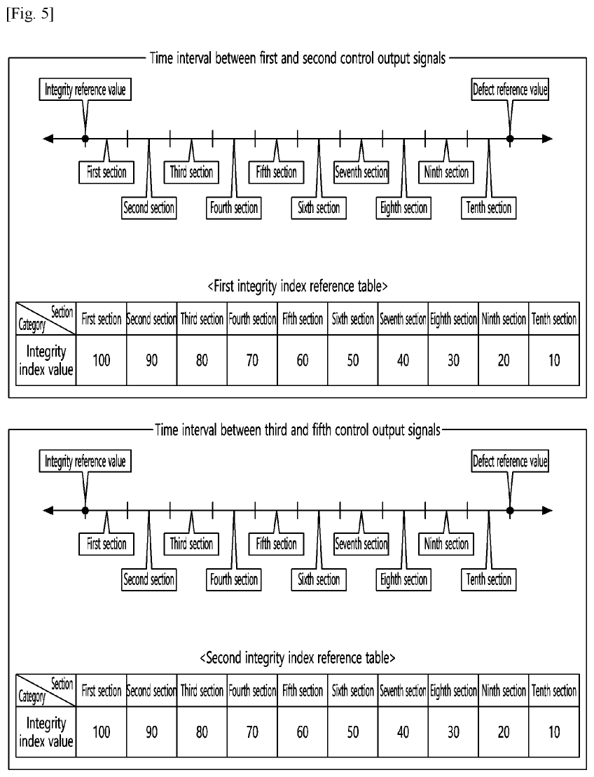

FIG. 5 is a view illustrating a setting procedure according to an exemplary embodiment of the present invention.

The setting procedure S42 is a procedure of setting a section partitioned between the integrity reference value and the defect reference value to a first section, a second section, . . . , and an n-th section sequentially from the integrity reference value and at the same time establishing the integrity index reference table by setting an integrity index value for each section.

Referring to FIG. 5, in the partitioning procedure S41, when the section between the integrity reference value and the defect reference value is partitioned into 10 sections, the partitioned sections are set as a first section, a second section, . . . , and a tenth section from the integrity reference value and then an integrity index value for each section is set to establish the integrity index reference table. In the integrity index detecting method 100 for a device by means of multiple control output signals of the present invention, the integrity index value is limited to the range from minimum 10 to maximum 100 and the limited integrity index value is assigned to each section to detect the integrity of the device.

Further, the integrity index value is limited to the range of 10 to 100 and when a value of the integrity index is large, a state of the device is set to be sound and when the value of the integrity index is small, the state of the device is set to be defective. However, the limiting and setting of the range of the integrity index value are arbitrarily determined as an example and the integrity index value may be determined to various ranges and settings.

Here, for the convenience of description, an integrity index reference table for the integrity and defect reference values for the time interval value between the first and second output signals is referred to as a first integrity index reference table and an integrity index reference table for the integrity and defect reference values for the time interval value between the third and fifth output signals is referred to as a second integrity index reference table.

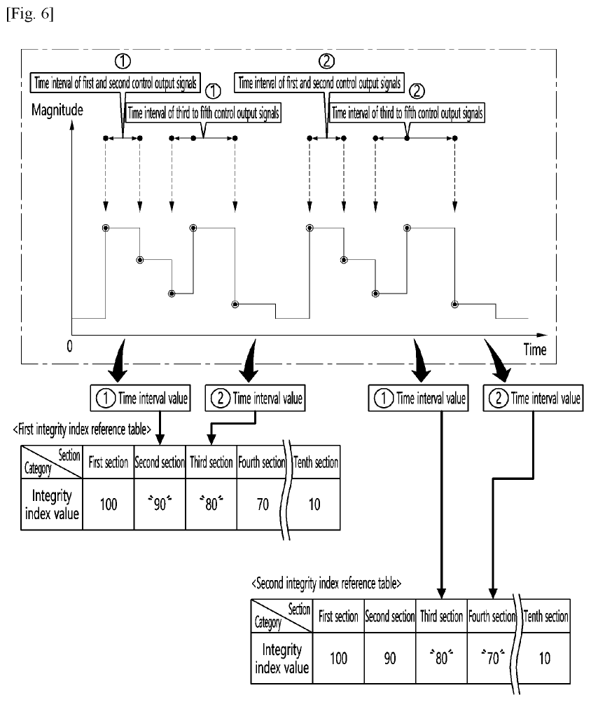

FIG. 6 is a view illustrating a detecting procedure according to an exemplary embodiment of the present invention.

The detecting procedure S43 is a procedure of applying the time interval value between the control output signals measured and collected in the device in real time to the integrity index reference table to detect a section corresponding to the measured time interval value and extract the integrity index value of the detected section.

Referring to FIG. 6, in order to control the operation of the device in real time, among control output signals output from the controller, a time interval between the first control output signal and the second control output signal and a time interval between the third control output signal and the fifth control output signal are collected and measured, respectively. The time interval value between the first and second control output signals is applied to the first integrity index reference table to detect a section corresponding to the collected time interval value and extract (acquire) an integrity index value corresponding to the detected section and the time interval value between the third and fifth control output signals is applied to the second integrity index reference table to detect a section corresponding to the collected time interval value and extract (acquire) an integrity index value corresponding to the detected section.

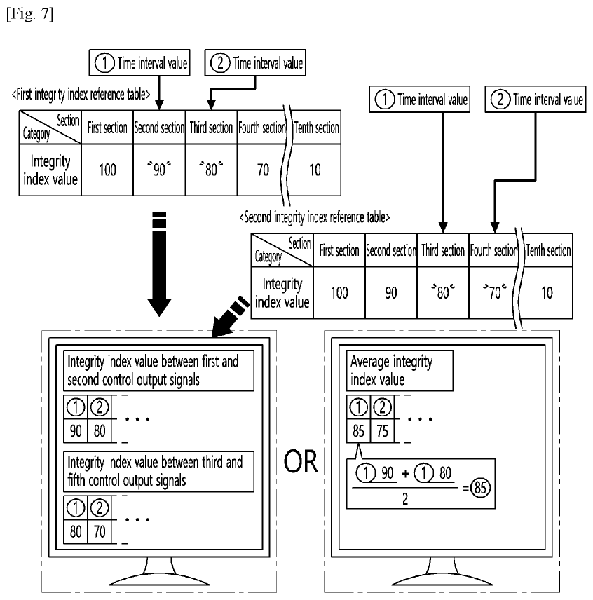

FIG. 7 is a view illustrating an example of providing an average integrity index value according to an exemplary embodiment of the present invention.

In the outputting step S50, the integrity index value detected in the detecting step S40 is output to provide the integrity index value to the manager through a normal monitor. As illustrated in FIG. 7, the integrity index value for the time interval value between the first and second control output signals and the integrity index value for the time interval value between the third and fifth control output signals extracted in the detecting step S40 may be independently output and provided or an average of the extracted integrity index values is calculated to be output as one average integrity index value.

That is, the integrity index value of the device which is extracted and provided in real time through the detecting step S40 allows a manager to clearly recognize the integrity state of the device to induce the manager to effectively handle (inspect/repair) according to the integrity of the device.

In the meantime, the detecting result for the integrity of the device may be output and provided in various methods according to an environment (situation) in which the device operates through the outputting step S50 so that a usage versatility of the integrity index detecting method of the present invention may be ensured.

The integrity index detecting method 100 for a device by means of multiple control output signals of the present invention which detects the integrity of the device by the above-described procedure, after establishing an integrity index reference table based on an integrity reference value set based on information collected from a normal device and a defect reference value set based on information collected from a device before a malfunction occurs, outputs an integrity index value indicating an integrity of the device in real time by applying time information collected from the device in real time to the integrity index reference table to provide the integrity index value to a manager, thereby allowing the manager to clearly recognize a real-time integrity of the device by means of the integrity index to establish a plan for inspection or management of the device by himself to very actively and stably perform the overall management of the device to significantly reduce safety accident and losses of money due to the sudden malfunction of the device.

Although the integrity index detecting method 100 for a device by means of multiple control output signals has been described based on the control output signal output from the controller to the device, when the technique is described based on a control input signal which is output from the controller to be input to the device, the same effect may also be expected.

The present invention has been described with reference to the exemplary embodiment illustrated in the drawing, but the exemplary embodiment is only illustrative and the present invention is not limited thereto. Further, it would be appreciated by those skilled in the art that various modifications and equivalent exemplary embodiments may be made. Further, those skilled in the art may modify the present invention without departing from the spirit of the present invention. Accordingly, the scope of claiming the rights of the present invention is not defined within the scope of the detailed description, but may be limited by the following claims and the technical spirit thereof.

The exemplary embodiment according to the present invention may be implemented by various means, for example, a hardware, a firmware, a software, and a combination thereof. When the exemplary embodiment is implemented by the hardware, one exemplary embodiment of the present invention may be implemented by one or more of application specific integrated circuits (ASICs), digital signal processors (DSPs), digital signal processing devices (DSPDs), programmable logic devices (PLDs), field programmable gate arrays (FPGAs), processors, controllers, microcontrollers, or microprocessors.

Further, in the case of the implementation by firmware or software, the exemplary embodiment of the present invention may be implemented in the form of a module, a procedure, or a function which performs functions or operations described above to be recorded in a recording medium which is readable by various computer means. The recording medium may include solely a program instruction, a data file, and a data structure or a combination thereof. The program instruction recorded in the recording medium may be specifically designed or constructed for the present disclosure or known to those skilled in the art of a computer software to be used. For example, the recording medium includes a hardware device which is specifically configured to store or execute a program instruction, such as magnetic media such as a hard disk, a floppy disk, and a magnetic tape, optical media such as a compact disk read only memory (CD-ROM) or a digital video disk (DVD), magneto-optical media such as a floptical disk, a ROM, a random access memory (RAM), and a flash memory. Examples of the program instruction include not only a machine language code which is created by a compiler but also a high level language code which may be executed by a computer using an interpreter. The hardware device may operate as one or more software modules in order to perform the operation of the present disclosure and vice versa.

Further, the device or the terminal according to the present invention may be driven by an instruction which causes one or more processors to perform the above-described functions and processes. For example, such an instruction may include interpreted instructions such as script instructions of JavaScript or ECMA script instructions, an executable code, or other instructions stored in a computer readable medium. Moreover, the device according to the present invention may be implemented as a distributed type over a network, such as a server farm, or may be implemented in a single computer device.

A computer program (also known as a program, software, software application, script or code) which is installed in the device according to the present invention and executes the method according to the present invention may be written in any form of a programming language including a compiled or interpreted language or a priori or procedural language. It can be deployed in any form including standalone programs, modules, components, subroutines or other units suitable to be used in a computer environment. The computer program does not necessarily correspond to a file of the file system. The program may be stored in a single file provided to a requested program, in multiple interacting files (for example, a file which stores one or more modules, subprograms, or a part of code), or in a part of a file which holds other programs or data (for example, one or more scripts stored in a markup language document). The computer program is located at one site or distributed over a plurality of sites to be deployed to be executed on multiple computers which are interconnected by a communication network or one computer.

For the convenience of description, even though the drawings have been separately described, exemplary embodiments illustrated in the drawings are designed to be merged to implement a new exemplary embodiment. Further, according to the present invention, the configuration and method of exemplary embodiments as described above may not be applied with limitation, but the exemplary embodiments may be configured by selectively combining all or a part of each exemplary embodiment such that various modifications may be made.

Preferred exemplary embodiments of the present invention have been illustrated and described above, but the present invention is not limited to the above-described specific exemplary embodiments, it is obvious that various modifications may be made by those skilled in the art, to which the present invention pertains without departing from the gist of the present invention, which is claimed in the claims, and such modifications should not be individually understood from the technical spirit or prospect of the present invention.

The present invention may be applied to various device inspection technical fields.

1. An integrity index detecting method for a device by means of multiple control output signals, the method comprising:
an integrity information collecting step S10 of measuring and collecting at least one time interval between a control output signal and another control output signal among multiple control output signals output from a controller to perform an operation in a normal state of a device which receives the multiple control output signals output from the controller to operate;
a defect information collecting step S20 of measuring and collecting at least one time interval between a control output signal and another control output signal among multiple control output signals output from the controller to allow the device which receives the multiple control output signals output from the controller to operate to perform one operation in a state before a malfunction occurs and collecting a time interval between a control output signal different from one or more control output signals collected in the integrity information collecting step S10 and the same control output signal;
a setting step S30 of setting an integrity reference value and a defect reference value for the time interval between the control output signals based on the time interval information between the control output signals collected in the integrity and defect information collecting steps S10 and S20;
a detecting step S40 of collecting the time interval between a control output signal different from one or more control output signals collected in the integrity information collecting step S10 and the same control output signal among multiple control output signals output from the controller to perform an operation of the device in real time and detecting an integrity index value of the device by comparing the collected time interval value between the control output signals and the integrity and defect reference values set in the setting step S30; and
an outputting step S50 of outputting the integrity index value detected in the detecting step S40 to provide the integrity index value to a manager,
wherein when in the integrity and defect information collecting steps S10 and S20, a plurality of time intervals between the control output signals is collected, integrity and defect reference values for the plurality of collected time intervals between the control output signals are set in the setting step S30, respectively.

2. The integrity index detecting method of claim 1, wherein the detecting step S40 includes:
a partitioning procedure S40 of partitioning a section between the integrity reference value and the defect reference value for the time interval between the control output signals set in the setting step S30 into at least two sections;
a setting procedure S42 of setting the section partitioned between the integrity reference value and the defect reference value to a first section, a second section, . . . , and an n-th section sequentially from the integrity reference value and at the same time establishing the integrity index reference table by setting an integrity index value for each section; and
a detecting procedure S43 of applying the time interval value between the control output signals measured and collected in the device in real time to the integrity index reference table to detect a section corresponding to the measured time interval value and extract the integrity index value of the detected section.

3. The integrity index detecting method of claim 2, wherein when in the integrity and defect information collecting steps S10 and S20, a plurality of time intervals between the control output signals is collected to set integrity and defect reference values for the time interval between the respective control output signals, in the detecting step S40, integrity index reference tables for the integrity and defect reference values are individually established by means of the partitioning procedure S41 and the setting procedure S42,
in the detecting step S43, the time interval values between a plurality of control output signals measured and collected in the device in real time to the integrity index reference table established for each time interval to extract, respectively, an integrity index value for the time interval values between the plurality of control output signals measured in real time, and
in the outputting step S50, the integrity index values for the time interval values between the plurality of control output signals measured in real time in the detecting step S40 are independently output to be provided or an average of the extracted integrity index values is calculated to be output and provided as one average integrity index value.
